(19) United States
(12) Patent Application Publication
(10) Pub. No.: US 2023/0086420 A1
(43) Pub. Date: Mar. 23, 2023

(54) SELF ALIGNED QUADRUPLE PATTERNING INTERCONNECTS

(71) Applicant: INTERNATIONAL BUSINESS MACHINES CORPORATION, Armonk, NY (US)

(72) Inventors: Hsueh-Chung Chen, Cohoes, NY (US); Chanro Park, Clifton Park, NY (US); Koichi Motoyama, Clifton Park, NY (US); Chih-Chao Yang, Glenmont, NY (US)

(21) Appl. No.: 17/479,660

(22) Filed: Sep. 20, 2021

(51) Int. Cl. H01L 21/768; H01L 21/033; H01L 23/532; H01L 23/522

(52) U.S. Cl. CPC H01L 21/76837; H01L 21/0337; H01L 21/7682; H01L 21/76816; H01L 21/76829; H01L 21/76879; H01L 23/5222; H01L 23/5329; H01L 23/53242

(57) ABSTRACT

Methods for forming conductive lines and integrated chips include forming a mandrel on an etch stop layer. First spacers are formed on sidewalls of the mandrel. The mandrel is etched away. Conductive lines are formed on sidewalls of the first spacers. The first spacers are etched away. Dielectric spacers are formed between the conductive lines.

### BACKGROUND

The present invention generally relates to integrated chip manufacture, and, more particularly, to the fabrication of conductive interconnects.

As semiconductor device fabrication technology improves, and component size continues to decrease, new materials are sought to improve device characteristics and yield. Additionally, consistently fabricating devices at small sizes, particularly in interconnects, poses challenges for device reliability and consistency.

### SUMMARY

A method for forming conductive lines includes forming a mandrel on an etch stop layer. First spacers are formed on sidewalls of the mandrel. The mandrel is etched away. Conductive lines are formed on sidewalls of the first spacers. The first spacers are etched away. Dielectric spacers are formed between the conductive lines.

A method for forming conductive lines includes forming a mandrel on an etch stop layer using a photolithographic patterning technology that has a minimum feature size. The mandrel is formed at the minimum feature size of the photolithographic patterning technology. Spacer material is conformally deposited on the mandrel. Spacer material is selectively and anisotropically etched away from horizontal surfaces to form first spacers on sidewalls of the mandrel. The mandrel is etched away. Conductive material is deposited on the first spacers at a consistent thickness using a conformal deposition process. Conductive material is selectively and anisotropically etched away from horizontal surfaces to form conductive lines on sidewalls of the first spacers. The first spacers are etched away. Dielectric spacers are formed between the conductive lines.

An integrated chip includes an etch stop layer on an underlying layer. Parallel conductive lines that are formed directly on the etch stop layer. The parallel conductive lines have a thickness of that is consistent to within one Angstrom. Dielectric spacers are positioned between adjacent conductive lines of the plurality of parallel conductive lines.

An integrated chip includes an etch stop layer on an underlying layer. Parallel conductive lines are formed directly on the etch stop layer, having a thickness of the conductive lines that is consistent to within one Angstrom. Dielectric spacers are positioned between adjacent conductive lines of the parallel conductive lines.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is cross-sectional view of a step in the fabrication of conductive lines for an integrated chip, showing a first dielectric layer on an etch stop layer, in accordance with an embodiment of the present invention;

FIG. 2 is cross-sectional view of a step in the fabrication of conductive lines for an integrated chip, showing the formation of mandrels from the first dielectric layer, in accordance with an embodiment of the present invention;

FIG. 3 is cross-sectional view of a step in the fabrication of conductive lines for an integrated chip, showing the deposition of a second dielectric layer over the mandrels, in accordance with an embodiment of the present invention;

FIG. 4 is cross-sectional view of a step in the fabrication of conductive lines for an integrated chip, showing the anisotropic etch of the second dielectric layer to remove the material of the second dielectric layer from horizontal surfaces, in accordance with an embodiment of the present invention;

FIG. 5 is cross-sectional view of a step in the fabrication of conductive lines for an integrated chip, showing the removal of the mandrels using a selective etch to leave the first spacers in place on the etch stop layer, in accordance with an embodiment of the present invention;

FIG. 6 is cross-sectional view of a step in the fabrication of conductive lines for an integrated chip, showing the deposition of a conductive layer over the first spacers at a consistent thickness, in accordance with an embodiment of the present invention;

FIG. 7 is cross-sectional view of a step in the fabrication of conductive lines for an integrated chip, showing the selective, anisotropic etch of the conductive layer to remove the material of the conductive layer from horizontal surfaces, in accordance with an embodiment of the present invention;

FIG. 8 is cross-sectional view of a step in the fabrication of conductive lines for an integrated chip, showing the selective removal of the first spacers to leave the conductive lines in place, in accordance with an embodiment of the present invention;

FIG. 9 is cross-sectional view of a step in the fabrication of conductive lines for an integrated chip, showing the formation of dielectric spacers from a solid dielectric material between the conductive lines, in accordance with an embodiment of the present invention;

FIG. 10 is cross-sectional view of a step in the fabrication of conductive lines for an integrated chip, showing the formation of dielectric spacers from a dielectric material that pinches off between the conductive lines to enclose cavities, in accordance with an embodiment of the present invention; and

FIG. 11 is a block/flow diagram of a method for forming conductive lines in an integrated chip, in accordance with an embodiment of the present invention.

### DETAILED DESCRIPTION

Ruthenium has been considered for device interconnects, due to its low resistivity and high reliability at small dimensions. For ruthenium interconnects, both subtractive etches and damascene processes can be used. However, for subtractive processing, dry etching a thick ruthenium film at a tight pitch is difficult. For damascene processes, line wiggling can result when filling in ruthenium at a tight pitch. Line wiggling refers to the appearance of metal lines, where the lines undulate along their length as a result of manufacturing variability. In either case, the ruthenium lines suffer from manufacturing variability, which can decrease device yield.

A self-aligned quadruple patterning (SAQP) process may be used to form conductive interconnects. Rather than using the SAQP process to define trench lines that are etched into an underlying dielectric, with the trenches being subsequently filled with conductive material, a conductive material may be deposited as one of the sidewall layers in the SAQP process itself. The process is significantly simpler than one where patterns are transferred into a final dielectric, and furthermore produces metal lines at a consistent line width and with little wiggling.

In addition, because the final dielectric between the conductive lines may be formed after the conductive lines have been formed, more options are available for the structure of the final dielectric. In addition to the option of filling in a solid dielectric between the conductive lines, these spaces may be filled with air-gapped spacers, using a dielectric material and deposition process that pinches off the gap between the conductive lines. These air-gapped spacers may have effective dielectric constants that are lower than may be achieved using solid spacers, which can decrease the capacitance between adjacent lines.

Referring now to FIG. 1, a step in the fabrication of conductive lines in an integrated chip is shown. A first dielectric layer 104 is formed on an etch stop layer 102. The etch stop layer 102, in turn, may be formed on an underlaying layer 101. The underlaying layer 101 may include any appropriate substrate, such as a semiconductor substrate, a semiconductor-on-insulator substrate, a device layer, or another interconnect layer.

The underlying layer 101 may include an underlying device layer or interconnect layer. In some cases, the underlying layer may include a semiconductor substrate. In some cases, the underlying layer 101 may include a device layer with an interlayer dielectric that forms most of the top surface of the underlying layer 101. Thus, the underlying layer 101 may include any appropriate layer or combination of layers in an integrated chip.

The underlying layer 101 may include a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the underlying layer 101 may also include a semiconductor on insulator (SOI) substrate.

The etch stop layer 102 may be formed form any material having appropriate etch selectivity. For example, the etch stop layer 102 may be formed from silicon carbonitride (SiCN), silicon nitride (SiN), aluminum oxide (AlN), or aluminum nitride (AlN). The etch stop layer 102 may therefore protect the underlying layer 101 from subsequent etches that are used to fabricate the conductive lines.

The first dielectric layer 104 may be formed from any appropriate material. Although referred to herein as a dielectric, in some cases the first dielectric layer 104 may be removed in its entirety in the final device. As such, the electrical properties of the first dielectric layer 104 are less important than its etch selectivity with respect to the materials of other layers. As such, the first dielectric layer 104 may be formed from a dielectric material, such as silicon nitride, or other materials, such as amorphous silicon or an organic planarizing layer.

For example, the etch stop layer 102 may be formed from a material that has etch selectivity with respect to the first dielectric layer 104, such that the first dielectric layer 104 may be patterned in subsequent steps without damaging the underlying layer 101. As used herein, the term “selective” in reference to a material removal process denotes that the rate of material removal for a first material is greater than the rate of removal for at least another material of the structure to which the material removal process is being applied.

This process may be applied at any appropriate stage in the fabrication of an integrated chip. For example, patterning metal lines may applicability in a back-end-of-line (BEOL) process. If the underlying layer 101 is a device layer, such as may be fabricated during front-end-of-line (FEOL) processes, then one or more layers of metal lines may be formed as interconnects on top of the underlying layer 101. Additionally, the BEOL portion of the integrated chip may have multiple such layers of interconnections, such that the underlying layer 101 may be another layer of interconnects, with its own set of metal lines and vias.

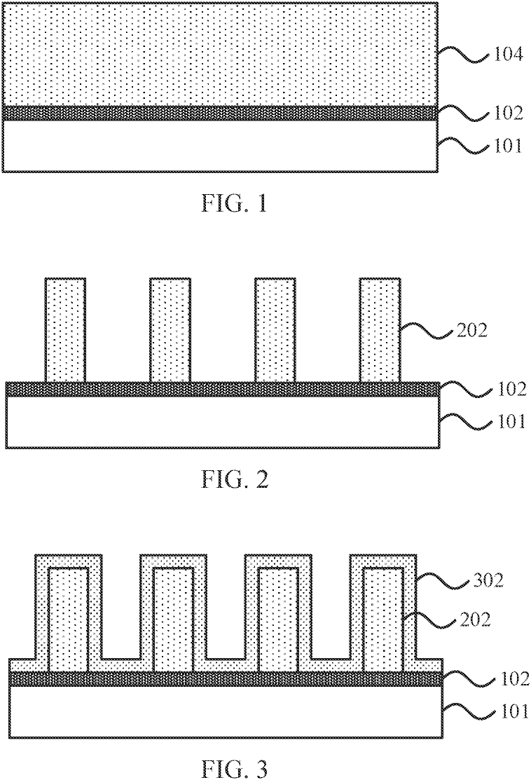

Referring now to FIG. 2, a step in the fabrication of conductive lines in an integrated chip is shown. The first dielectric layer 104 is patterned to form mandrels 202. The first dielectric layer 104 may be patterned using any appropriate process. One exemplary process is a photolithographic process that deposits a mask material over the first dielectric layer 104 and exposes the material to an appropriate wavelength of light to cause the mask material to cure and form a pattern mask. The first dielectric layer 104 may then be etched using a reactive ion etch (RIE) that is selective to the material of the first dielectric layer 104, such that the shape of the mandrels 202 is defined by the shape of the pattern mask. This selective anisotropic etch should stop on the etch stop layer 102, to prevent damage to the underlying layer 101. After patterning the mandrels 202, any leftover mask material used in the photolithographic process may be removed.

The photolithographic process may have a minimum feature size, and the mandrels 202 may be formed at the minimum feature size. In some embodiments, the mandrels 202 may be formed with a width that is three times the width of the ultimate metal lines to be formed. Thus, for forming metal lines that are 10 nm in width, mandrels 202 may have a width of 30 nm, with the metal lines that are ultimately formed having a thickness that is less than the minimum feature size of the photolithographic process. The mandrels may be formed with a pitch that is sufficient to perform self-aligned quadrature patterning, providing even spacing to the metal lines that are to be formed. In the case of metal lines that have a width of 10 nm, then the mandrels 202 may be formed with a pitch of 80 nm, for example measured from the left side of a mandrel to the left side of an adjacent mandrel.

RIE is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface. Other examples of anisotropic etching that can be used at this point of the process include ion beam etching, plasma etching or laser ablation.

Referring now to FIG. 3, a step in the fabrication of conductive lines in an integrated chip is shown. A second dielectric layer 302 is formed over the mandrels 202. The dielectric layer 302 may be formed by any appropriate conformal deposition process, such as chemical vapor deposition (CVD) or atomic layer deposition (ALD). The dielectric layer 302 may thereby be formed with a consistent thickness on vertical and horizontal surfaces of the mandrels 202 and the exposed portions of the etch stop layer 102. It is specifically contemplated that the dielectric layer 302 may be formed to a thickness that matches a thickness of the metal lines that are to be formed, but it should be understood that other spacings and other thicknesses are also contemplated.

As with the first dielectric layer 104, the second dielectric layer 302 may subsequently be removed, so its electrical properties are secondary to its available etch selectivity. The material of the second dielectric layer should be selectively etchable with respect to the material of the mandrels 202 and the etch stop layer 102. Exemplary materials for the second dielectric layer 302 may include aluminum oxide, aluminum nitride, or silicon nitride.

CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use ALD, chemical precursors react with the surface of a material one at a time to deposit a thin film on the surface.

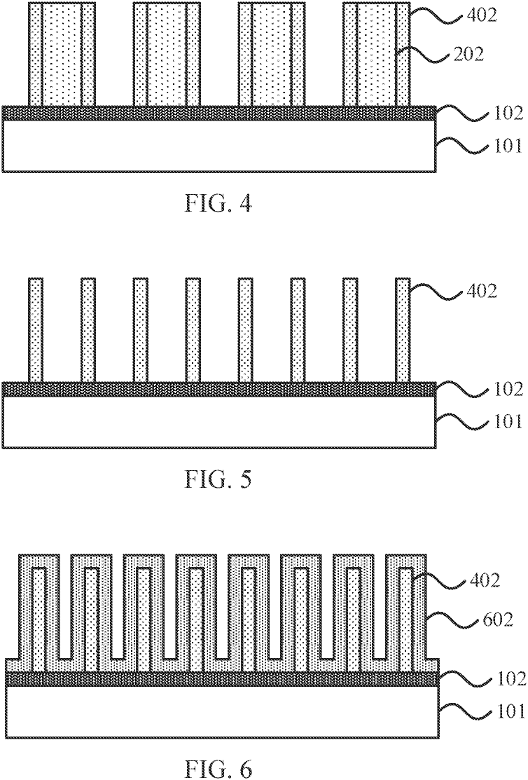

Referring now to FIG. 4, a step in the fabrication of conductive lines in an integrated chip is shown. A selective anisotropic etch, such as an RIE, may be used to remove material from the horizontal surfaces of the second dielectric layer 302. The selective anisotropic etch may be timed to remove a predetermined thickness of material, such that all material is removed from the second dielectric layer 302 in horizontal regions, leaving sidewall spacers 402 intact. Although the etch is shown as precisely removing the spacer material from the horizontal surfaces, it should be understood that some overetch is possible without damaging the conductive lines that are to be formed in subsequent steps. The width of the spacers 402 defines the spacing of the conductive lines, but the process is less sensitive to the height of the spacers 402.

Referring now to FIG. 5, a step in the fabrication of conductive lines in an integrated chip is shown. A selective etch is used to etch away the mandrels 202. This selective etch may be isotropic or anisotropic. An isotropic etch may remove material in more than one direction, such as by a wet or dry chemical etch. The etch may selectively remove the material of the mandrels 202, without substantially damaging the sidewall spacers 402 or the etch stop layer 102. The sidewall spacers 402 thus remain free-standing on the etch stop layer 102, with spacing that was defined by the width of the mandrels 202. As shown, the sidewall spacers 402 may have a consistent spacing between them. However, it should be understood that the spacing between the sidewall spacers 402 may be determined by the selection of an appropriate mandrel thickness, mandrel pitch, and spacer thickness.

Referring now to FIG. 6, a step in the fabrication of conductive lines in an integrated chip is shown. A conductive layer 602 is formed with a consistent thickness over the sidewall spacers 402. Any appropriate conformal deposition process may be used, such as CVD or ALD, to deposit the conductive material on both horizontal and vertical surfaces. It is specifically contemplated that the conductive layer 602 may be formed from ruthenium, but it should be understood that any appropriate conductive material may be used instead. Exemplary conductive materials include tungsten, nickel, titanium, molybdenum, tantalum, copper, platinum, silver, gold, iridium, rhenium, rhodium, cobalt, and alloys thereof.

The thickness of the conductive layer 602 may be tightly controlled during the deposition process. For example, using an ALD deposition of ruthenium, the thickness of the conductive layer 602 may be controlled to within the sub-Angstrom range. In an illustrative ALD deposition performed between 200° C. and 210° C., a growth rate of 0.42 Å per cycle is possible. Depending on the deposition parameters, even finer control of the thickness may be achieved. Additionally, line wiggling is prevented, as this process creates the conductive layer 602 without a low-k dielectric patterning step, which could otherwise cause bending or buckling. This contrasts to processes where a low-k dielectric material may be etched first to create trenches, with metal lines being formed in the trenches.

Referring now to FIG. 7, a step in the fabrication of conductive lines in an integrated chip is shown. A selective anisotropic etch may be used to remove material from the conductive layer 602 from horizontal surfaces, thereby exposing the top surfaces of the sidewall spacers 402 and portions of the etch stop layer 102. This leaves conductive lines 702 on sidewalls of the sidewall spacers 402. Adjacent conductive liens 702 may be separated by a gap or by a sidewall spacer 402.

Notably, the conductive lines 702 may be formed directly on the etch stop layer 104, without any intervening dielectric layer. Such dielectric remnants may occur when a SAQP process is used to create a pattern that is subsequently transferred to an underlying final dielectric layer. For example, such a process may be used to define trenches in the final dielectric layer for the formation of metal lines, but that process is prone to error and manufacturing variability. By using a metal deposition as the second set of sidewalls, transfer to a final dielectric layer is rendered unnecessary. Thus, the conductive lines 702 may be formed without any patterned dielectric material between them and the underlying layer 101.

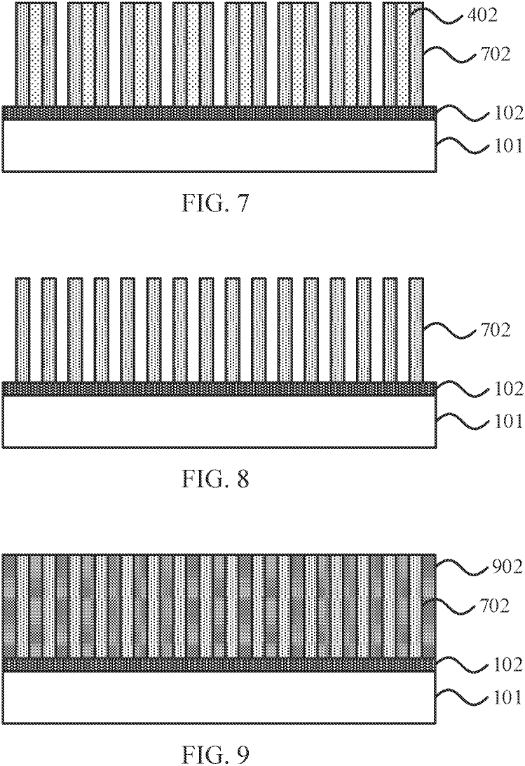

Referring now to FIG. 8, a step in the fabrication of conductive lines in conductive lines in an integrated chip is shown. The sidewall spacers 402 may be removed using any appropriately selective isotropic or anisotropic etch, leaving the conductive lines 702 standing free, directly on the etch stop layer 102. The conductive lines 702 are shown as being evenly spaced, but it should be understood that other spacings are possible, and may be set according to the thickness and positioning of the sidewall spaces 402 and the thickness of the conductive lines 702.

At this point, different options are available for forming dielectric material between the conductive lines 702. In some embodiments, solid dielectric material may be deposited between the conductive lines 702. In other embodiments, air-gapped dielectric material may be formed between the conductive lines 702. The dielectric spacing between the conductive lines may be formed in accordance with the needs of the design, for example, using air-gapped dielectric spacers to obtain spacers with specific electrical properties.

After fabrication of the conductive lines 702, the lines 702 may be further patterned in accordance with an integrated chip design. For example, lines 702 may be cut using any appropriate mask and etch process, to establish different regions of connectivity (not shown). Additionally, further layers of interconnects may be formed over the conductive lines 702, for example providing vias that connect lines 702 to other layers, and interconnects that connect lines 702 to one another. The conductive lines 702 may furthermore establish electrical contact with devices in the underlying layer 101, for example by forming an electrical connection to a device contact or an interconnect in the underlying layer 101.

Additional back-end processes may also be performed, for example to finish the integrated chip and to provide electrical connections to off-chip devices. For example, protective layers may be formed over the conductive lines 101, and solder bumps may be added to simplify installation of the integrated chip. Thus, while only a single layer of conductive lines 702 is shown, the underlying layer may include substantial complexity, and additional layers with additional conductive lines, additional devices, and any other appropriate structure, may be formed as well. Thus, the finished integrated chip may have substantial features beyond those which are explicitly described herein.

Referring now to FIG. 9, a step in the fabrication of conductive lines in an integrated chip with solid dielectric spacers is shown. A third dielectric layer may be deposited using any appropriate deposition process (e.g., CVD), filling the dielectric material to a height above the height of the conductive lines 702. Exemplary materials for the third dielectric material may include oxides or low-k dielectric films, such as SiCOH. Excess dielectric material may then be removed from the top using, e.g., a chemical mechanical planarization (CMP) process to create dielectric spacers 902 and to expose the top surfaces of the conductive lines 702. As used herein, the term “low-k” refers to a material that has a dielectric constant k that is lower than the dielectric constant of silicon dioxide. The term “ultra-low-k” refers to a material that has a dielectric constant substantially lower than that of silicon dioxide.

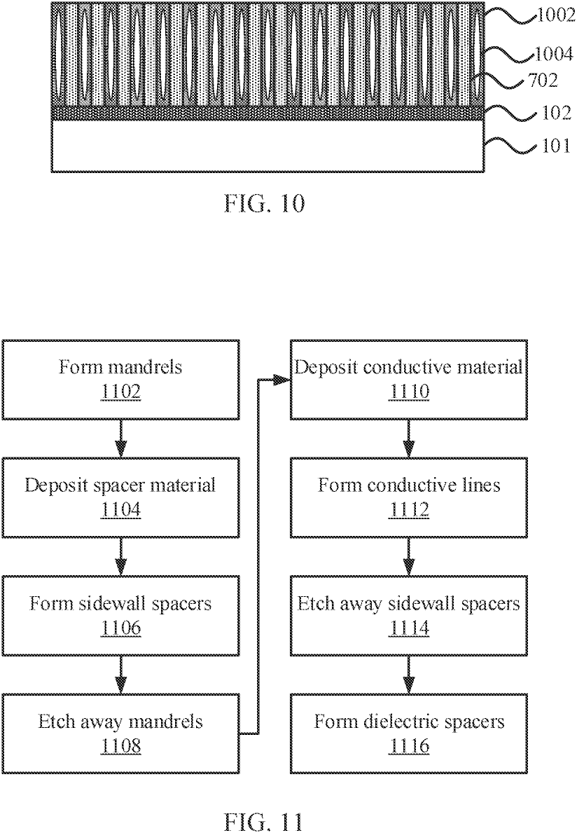

Referring now to FIG. 10, a step in the fabrication of conductive lines in an integrated chip with air-gapped spacers is shown. A third dielectric layer may be deposited using a deposition process and a material that causes the third dielectric layer to pinch off at the top, leaving air gaps 1004 in the third dielectric layer. The third dielectric layer may then be polished down to the height of the conductive lines 702, thereby exposing the conductive lines 702 and creating air-gapped spacers 1002. The cavities 1004 may be filled with a gas that was present at the time of formation, or may contain a relative vacuum.

The use of air-gapped spacers may be desirable to decrease capacitance between adjacent conductive lines 702. Whereas the dielectric material silicon dioxide has a dielectric constant k of roughly 3.9, the dielectric constant of a vacuum is 1 (by definition), and the dielectric constant of air is only marginally greater than that of vacuum. Thus, solid dielectric spacers 902 will result in capacitance between adjacent metal lines 702 that is significantly greater than the capacitance that would result with the use of air-gapped spacers 1002. The exact improvement would depend on the dielectric material that is used to form the air-gapped spacers 1002, as well as the proportion of the air-gapped spacers 1002 that are actually taken up by the cavities 1004.

Reduction of capacitance is of significant concern as device pitch continues to scale down. Stray capacitances in an integrated chip can limit the performance of the chip, particularly in highfrequency applications, and cause unwanted resonance with any inductances present in the chip. For example, a pair of adjacent conductive lines 702 may be modeled as a parallel plate capacitor, with each conductive line 702 being represented as one plate of the capacitor. The capacitance between the lines 702 may therefore be expressed as:

$$C = \frac{k {ε}_{0} A}{d}$$

where A is the area of the plates, d is the distance between the plates, ε₀ is the permittivity of free space, and k is the dielectric constant of the material between the plates. The capacitance is therefore inversely proportional to the distance between the plates—as device size scales down and the pitch between lines 702 decreases, the capacitance between the lines 702 increases. However, capacitance is also proportional to the dielectric constant k. Thus, the use of air-gapped spacers 1002 can substantially reduce the overall capacitance.

Furthermore, air-gapped spacers 1002 may provide benefits over the use of solid low-k materials. A low-k material, as used herein, refers to a material that has a dielectric constant k that is lower than that of silicon dioxide. Low-k materials can achieve dielectric constants between about 2 and about 3, but these materials can be difficult to work with. In particular, they can be susceptible to damage from subsequent fabrication processes.

Referring now to FIG. 11, a method of forming metal lines in an integrated chip is shown. Block 1102 forms mandrels 202, for example by patterning first dielectric layer 104. Block 1104 deposits spacer material 302 over the mandrels 202 using any appropriate conformal deposition process, and block 1106 forms sidewall spacers 402 from the spacer material 302 using a selective anisotropic etch that stops on the etch stop layer 102 and the mandrels 202. Block 1108 then etches away the mandrels 202 using any appropriate selective etching process, leaving the sidewall spacers 402.

Block 1110 deposits conductive material 602 over the sidewall spacers 402 using any appropriate conformal deposition process, and block 1112 forms conductive lines 702 from the conductive material 602 using a selective anisotropic etch that stops on the etch stop layer 102 and the sidewall spacers 402. Block 1114 then etches away the sidewall spacers 402, leaving the conductive lines 702.

Block 1116 forms dielectric spacers between the conductive lines 702. In some embodiments, the dielectric spacers may be solid spacers 902, formed by any appropriate deposition process and material. In other embodiments, the dielectric spacers may be air-gapped spacers 1002, which use a deposition process and material that cause deposited material to pinch off, leaving air gaps 1004 between the conductive lines 702.

It is to be understood that the present invention will be described in terms of a given illustrative architecture; however, other architectures, structures, substrate materials and process features and steps may be varied within the scope of the present invention.

It will also be understood that when an element such as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

The present embodiments may include a design for an integrated circuit chip, which may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other lowend applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements may be included in the compound and still function in accordance with the present principles. The compounds with additional elements will be referred to herein as alloys.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “coiiiprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, may be used herein for ease of description to describe one element’s or feature’s relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly. In addition, it will also be understood that when a layer is referred to as being “between” two layers, it can be the only layer between the two layers, or one or more intervening layers may also be present.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

Having described preferred embodiments of self-aligned quadruple patterning interconnects (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A method for forming conductive lines, comprising:
forming a mandrel on an etch stop layer;
forming first spacers on sidewalls of the mandrel;
etching away the mandrel;
forming conductive lines on sidewalls of the first spacers;
etching away the first spacers; and
forming dielectric spacers between the conductive lines.

2. The method of claim 1, wherein the conductive lines are formed directly on the etch stop layer.

3. The method of claim 1, wherein the conductive lines are formed from conformally deposited ruthenium.

4. The method of claim 1, wherein forming the dielectric spacers between the conductive lines includes depositing a dielectric material that pinches off to enclose a cavity to form air-gapped dielectric spaces.

5. The method of claim 1, wherein the conductive lines are formed to a thickness that is one eighth of a pitch between the mandrels.

6. The method of claim 1, further comprising forming the etch stop layer on an underlying interconnect layer.

7. The method of claim 1, wherein forming the conductive lines comprises depositing conductive material at a consistent thickness on the first spacers using a conformal deposition process and then selectively anisotropically etching the conductive material away from horizontal surfaces.

8. The method of claim 7, wherein conformally depositing the conductive material includes an atomic layer deposition process that provides a thickness of the conductive lines that is consistent to within one Angstrom.

9. The method of claim 1, wherein forming the first spacers comprises conformally depositing spacer material on the mandrel and then anisotropically etching the spacer material away from horizontal surfaces.

10. The method of claim 1, wherein the mandrels are formed using a photolithographic process that has a minimum features size, and wherein the mandrels are formed at the minimum feature size.

11. A method for forming conductive lines, comprising:
forming a mandrel on an etch stop layer using a photolithographic patterning technology that has a minimum feature size, wherein the mandrel is formed at the minimum feature size of the photolithographic patterning technology;
conformally depositing spacer material on the mandrel;
selectively anisotropically etching spacer material away from horizontal surfaces to form first spacers on sidewalls of the mandrel;
etching away the mandrel;
depositing conductive material on the first spacers at a consistent thickness using a conformal deposition process;
selectively anisotropically etching conductive material away from horizontal surfaces to form conductive lines on sidewalls of the first spacers;
etching away the first spacers; and
forming dielectric spacers between the conductive lines.

12. The method of claim 11, wherein the conductive lines are formed directly on the etch stop layer.

13. The method of claim 11, wherein the conductive lines are formed from conformally deposited ruthenium.

14. The method of claim 11, wherein forming the dielectric spacers between the conductive lines includes depositing a dielectric material that pinches off to enclose a cavity to form air-gapped dielectric spaces.

15. The method of claim 11, wherein the conductive lines are formed to a thickness that is one eighth of a pitch between the mandrels.

16. The method of claim 11, further comprising forming the etch stop layer on an underlying interconnect layer.

17. An integrated chip comprising:
an etch stop layer on an underlying layer;
a plurality of parallel conductive lines that are formed directly on the etch stop layer, the plurality of parallel conductive lines having a thickness of that is consistent to within one Angstrom; and
a plurality of dielectric spacers, each between adjacent conductive lines of the plurality of parallel conductive lines.

18. The integrated chip of claim 17, wherein the plurality of dielectric spacers are air-gapped spacers, each of the air-gapped spacers including a respective cavity that is enclosed by pinched-off dielectric material.

19. The integrated chip of claim 17, wherein each conductive line of the plurality of parallel conductive lines has a respective thickness that is less than a minimum feature size of a photolithographic process used to fabricate the integrated chip.

20. The integrated chip of claim 17, wherein the underlying layer includes one or more devices that electrically interface with the parallel conductive lines.
